(19) United States
(12) Patent Application Publication
(10) Pub. No.: US 2016/0141275 A1
(43) Pub. Date: May 19, 2016

(54) SEMICONDUCTOR POWER MODULE USING DISCRETE SEMICONDUCTOR COMPONENTS

(71) Applicant: LITTELFUSE, INC., Chicago, IL (US)

(72) Inventors: Richard J. Bono, Brownsville, TX (US); Koichiro Yoshimoto, Irving, TX (US)

(73) Assignee: LITTELFUSE, INC., Chicago, IL (US)

(21) Appl. No.: 14/547,222

(22) Filed: Nov. 19, 2014

(51) Int. Cl. H01L 25/07; H01L 25/18; H01L 23/492; H01L 23/043; H01L 23/373; H01L 23/31; H01L 21/56; H01L 23/00; H01L 25/00; H01L 23/367

(52) U.S. Cl. CPC H01L 25/072; H01L 25/50; H01L 25/18; H01L 23/4924; H01L 23/3675; H01L 23/3731; H01L 23/3107; H01L 21/565; H01L 24/83; H01L 24/32; H01L 24/49; H01L 24/85; H01L 24/73; H01L 24/92; H01L 23/043; H01L 2924/1203; H01L 2924/1301; H01L 2924/1304; H01L 2924/15747; H01L 2924/05032; H01L 2924/0532; H01L 2924/0542; H01L 2924/05442; H01L 2224/29187; H01L 2224/32245; H01L 2224/48108; H01L 2224/48227; H01L 2224/73265; H01L 2224/85801; H01L 2224/92247

(57) ABSTRACT

An electronic power module is disclosed. The module includes a baseplate and a plurality of internally isolated discrete electronic devices mounted to the baseplate such that their electrical leads are oriented away from the baseplate. Electrical leads may be coupled to a printed circuit board (PCB). Other features disclosed include a thermal interface material and an application-specific heat sink. The assembly may be overmolded via injection molding or potted using an encapsulant. Example electronic devices include thyristors, diodes, and transistors.

### BACKGROUND

Some electronic modules are constructed using a direct bonded copper (“DBC”) substrate. DBC substrates may be formed from a ceramic insulator with copper directly bonded to one side of the ceramic insulator. Although DBC substrates provide for increased thermal resilience of the semiconductor die, they drastically increase the difficulty of testing components before assembly. Additionally, assembly costs for DBC substrate components are high relative to non-DBC components. Furthermore, it is difficult to scale both components formed on DBC substrates. More specifically, it is difficult to scale the number of components possible to include on one device when the components are mounted to a DBC substrate. Additionally the number of circuit topologies available can be limited. The present disclosure is directed towards these concerns.

### SUMMARY

The following is a simplified summary in order to provide a basic understanding of some embodiments described herein. This summary is not an extensive overview, and it is not intended to identify key/critical elements or to delineate the scope thereof. Its sole purpose is to present some concepts in a simplified form as a prelude to the more detailed description that is presented later.

Various embodiments are generally directed towards an electronic device formed from a number of discrete semiconductor components that provide increased thermal resilience over conventional techniques. The electronic device according to various embodiments of the present disclosure may be scaled to provide a variety of different components and/or circuit topologies while still maintaining thermal resilience over conventional techniques.

In one embodiment, discrete electronic devices are mounted on a baseplate, preferably with electrical leads oriented away from the baseplate. An electronic device is typically understood to refer to a physical entity used in an electronic system to affect electrons or electrical fields. The baseplate may comprise a thermally conductive material, such as copper, to allow for the transfer of heat away from the internally isolated discrete electronic devices.

In one embodiment, the devices are mounted on the baseplate using a mechanical fastener, such as screws, spring clips, and the like. In one embodiment, each device has electrical leads formed at 90 degree angles to the baseplate to provide a through hole printed circuit board (“PCB”) mount. The assembly may be soldered into a PCB which provides the specific topology required. One or more application-specific heat sinks may be mounted onto the baseplate. The entire assembly may be overmolded by injection molded or potted using an encapsulant.

### BRIEF DESCRIPTION OF THE DRAWINGS

FIG. 1 is a block diagram illustrating a bottom view of an electronic device, arranged according to at least one embodiment of the present disclosure.

FIG. 2 is a block diagram illustrating a side view of the electronic device of FIG. 1.

FIG. 3 is a block diagram illustrating an electronic device potted with an encapsulant, arranged according to at least one embodiment of the present disclosure.

FIG. 4 is a block diagram illustrating an electronic device overmolded with an insulator, arranged according to at least one embodiment of the present disclosure.

FIG. 5 is a block diagram illustrating an electronic device operably connected to a PCB, arranged according to at least one embodiment of the present disclosure.

FIG. 6 is a block diagram illustrating an electronic device operably connected to a PCB and potted with an encapsulant, arranged according to at least one embodiment of the present disclosure.

FIG. 7 is a block diagram illustrating an electronic device operably connected to a PCB and overmolded with an insulator, arranged according to at least one embodiment of the present disclosure.

### DETAILED DESCRIPTION

The present disclosure will now be described more fully hereinafter with reference to the accompanying drawings. It is to be appreciated however, that the foregoing claims may be embodied in many different forms and should not be construed as being limited to the embodiments set forth herein. Rather, these embodiments are provided so that this disclosure will be thorough and complete, and will fully convey the scope of the claimed subject matter to those of ordinary skill in the art. In the drawings, like numbers refer to like elements throughout.

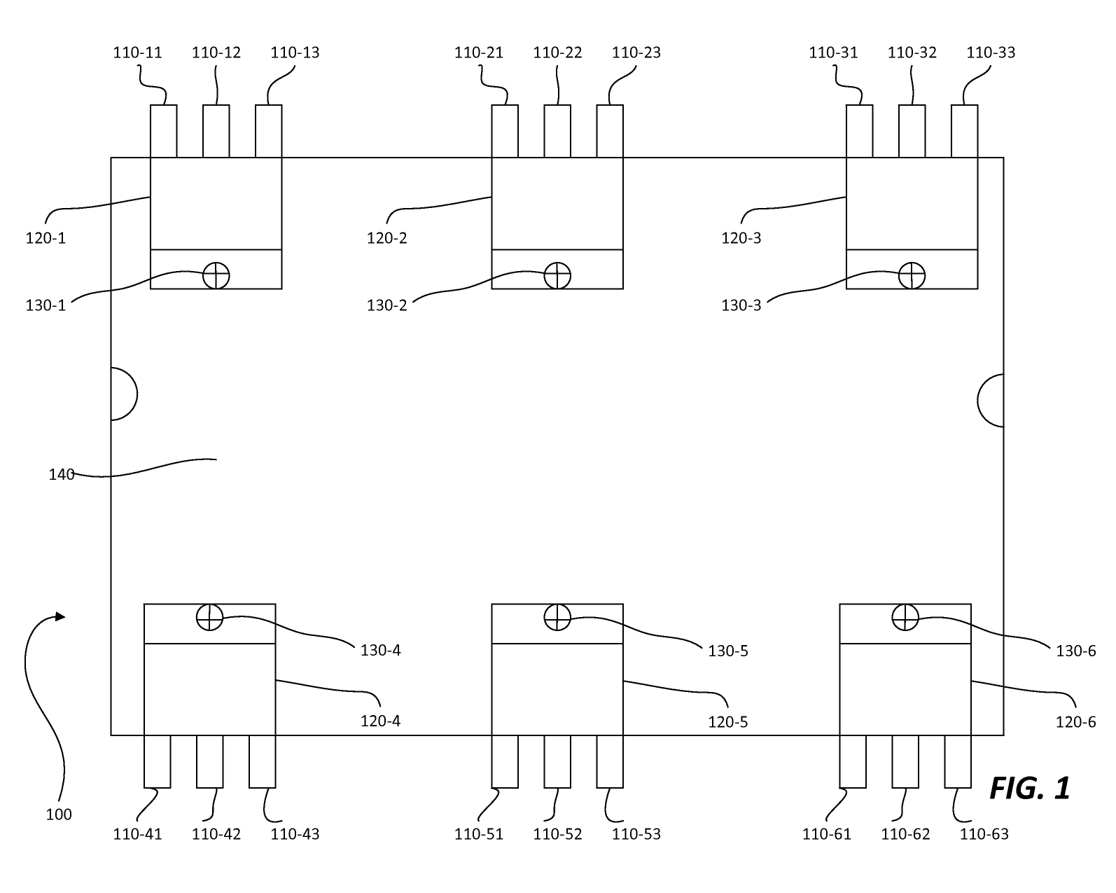

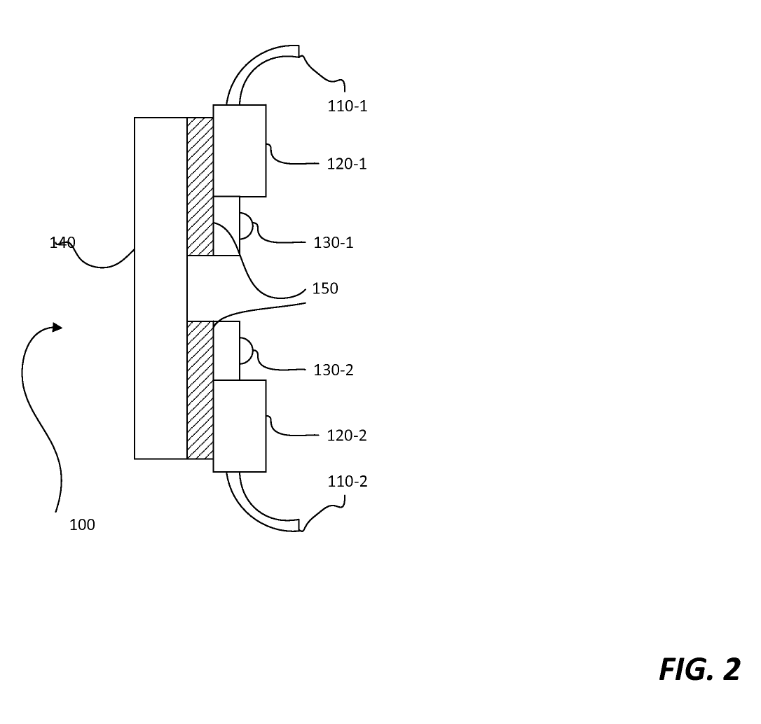

FIGS. 1-2 illustrate an electronic device 100 formed from a number of discrete electronic devices 120-a. In particular, FIG. 1 illustrates a bottom view of the device 100 while FIG. 2 illustrates a side view of the device 100. It is to be appreciated, that “a” as used herein may refer to any positive integer. Furthermore, although FIGS. 1-2 illustrate discrete electronic devices 120-1 to 120-6, examples are not to be limited in this context. More specifically, the device 100 may include any number of discrete electronic devices 120.

Turning more specifically to FIG. 1, the electronic device 100 includes discrete electronic devices 120-1, 120-2, 120-3, 120-4, 120-5, and 120-6. In general, the discrete electronic devices 120-a may be any of a variety of types of electronic devices, such as, for example, resistors, capacitors, thyristors, diodes, transistors, antennas, electro-mechanical devices, pizo-electrical devices, or the like. Furthermore, the discrete electronic devices 120-a may be any of a variety of discrete circuits, such as, for example, amplifiers, oscillators, converters, or the like.

In some examples, the discrete electronic devices are internally isolated from each other. More specifically, each discrete electronic device 120-a is electrically isolated from the other devices 120-a. In some examples, the discrete electronic devices 120-a may have a casing that operates to internally isolate the device. The casing may be made from metal, plastic, glass, ceramic, or another insulating material.

Some advantages of internal isolation include protection against impact and corrosion, stable holds for contact pins or leads (which are used to connect the device to external circuits), and dissipation of heat produced in the device. Furthermore, an advantage to using internally isolated discrete electronic devices 120-a in the device 100 is that each discrete electronic device 120-a may be tested before the device 100 is assembled and/or completely formed.

The device 100 further includes a baseplate 140. Each discrete electronic device 120-a is affixed to the baseplate 140. FIGS. 1-2 show the discrete electronic devices 120-a affixed to the baseplate by screws 130-a. In particular, discrete electronic devices 120-1 to 120-6 are shown affixed using screws 130-1 to 130-6, respectively. Examples, however are not to be limited in this context. Specifically, the discrete electronic devices 120-a may be affixed to the baseplate 140 by any of a variety of techniques, such as for example, riveting, crimping, welding, soldering, brazing, taping, cementing, or using adhesives (e.g., thermal epoxy, or the like.)

In general, the baseplate 140 may comprise any of a variety of thermally conductive materials. For examples, the baseplate 140 may be copper, silver, gold, aluminum, iron, steel, brass, bronze, mercury, graphite, or an alloy including one or more of these or other thermally conductive materials.

It is to be appreciated, that the discrete electronic devices 120-a may include any number of electrical leads 110-ab, with the number of leads being dependent upon the nature of each individual discrete electronic device 120-a. However, the discrete electronic devices 120-a are shows having three (3) electrical leads 110-ab for convenience and clarity. In particular, discrete electronic device 120-1 includes electrical leads 110-11, 110-12, and 110-13. Discrete electronic device 120-2 includes electrical leads 110-21, 110-22, and 110-23. Discrete electronic device 120-3 includes electrical leads 110-31, 110-32, and 110-33. Discrete electronic device 120-4 includes electrical leads 110-41, 110-42, and 110-43. Discrete electronic device 120-5 includes electrical leads 110-51, 110-52, and 110-53. Discrete electronic device 120-6 includes electrical leads 110-61, 110-62, and 110-63. Each discrete electronic device 120 may be an electronic device such as a thyristor, a diode, a transistor, or another type of electronic device. Each discrete electronic device 120 is internally isolated, meaning it has a casing that may be made from metal, plastic, glass, ceramics, or other materials. Each discrete electronic device 120 may include individual discrete components etched in silicon wafer.

Thermal interface material 150 is shown between the discrete electronic devices 120-a and baseplate 140. Thermal interface material 150 may be a viscous fluid substance with properties akin to grease, which increases the thermal conductivity of baseplate 140 and discrete electronic devices 120-a by filling air-gaps present due to imperfections in the surfaces of discrete electronic devices 120-a and baseplate 140, thereby allowing further heat dissipation. In one example, thermal interface material 150 may comprise metal oxide and nitride particles suspended in silicone thermal compounds. In other examples, thermal interface material 150 may comprise water, thermal grease, aluminum oxide, zinc oxide, steel, sodium fluoride aluminum, copper, silver, diamond, beryllium oxide, aluminum nitride, zinc oxide, silicon dioxide, gallium, or other materials.

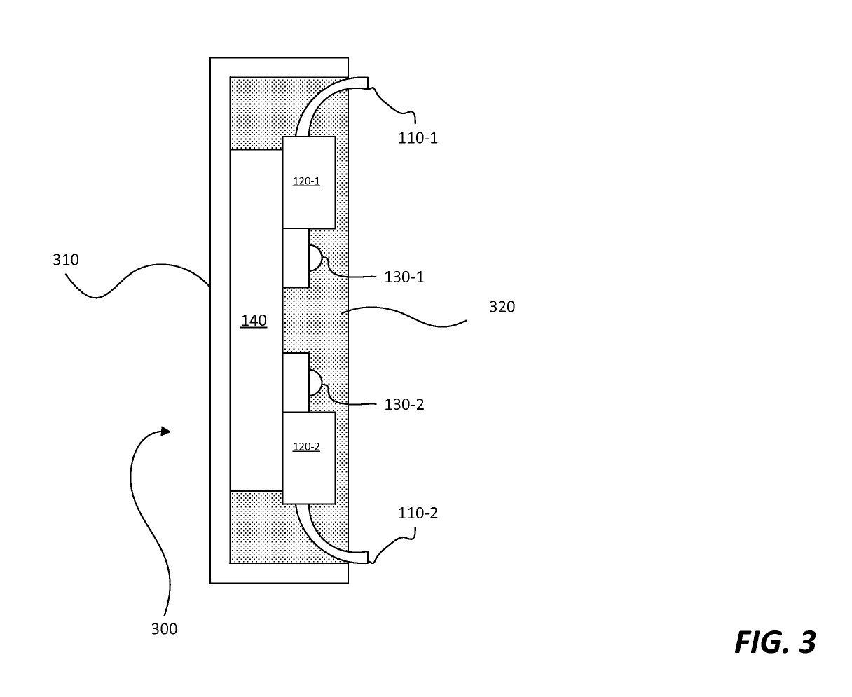

FIG. 3 illustrates electronic device 300 from a side view. FIG. 3 shows discrete electronic devices 120-1 and 120-2 affixed to baseplate 140 by screws 130-1 and 130-2 respectively. Examples, however are not to be limited in this context. Specifically, the discrete electronic devices 120-a may be affixed to the baseplate 140 by any of a variety of techniques, such as for example, riveting, crimping, welding, soldering, brazing, taping, cementing, or using adhesives (e.g., thermal epoxy, or the like.)

It is to be appreciated, that the discrete electronic devices 120-a may include any number of electrical leads 110-ab, with the number of leads being dependent upon the nature of each individual discrete electronic device 120-a. However, the discrete electronic devices 120-a are shown having electrical leads 110-1 and 110-2 for convenience and clarity. In this example, electrical leads 110-1 and 110-2 are oriented away from baseplate 140.

During normal operations, discrete electronic devices 120-a may generate significant amounts of heat. If the heat generated during the operation of discrete electronic devices 120-a is not removed, then discrete electronic devices 120-a or other devices near them may overheat, resulting in damage to discrete electronic devices 120-a, damage to devices near them, or causing degradation of performance. In this example, application specific heat sink 310 has been mounted onto baseplate 140 to assist in heat dissipation. There may be a need to balance the heat-dissipating requirements of the heat sink 310 with other factors. Heat sink 310 may crack, damage or separate from the electronic components they are attached to if the heat sink has a coefficient of thermal expansion significantly different from the baseplate 140 or other attached components. Also, many materials used to make heat sinks are relatively heavy. If discrete electronic devices 120-a or other parts of the assembly are subjected to vibration or impact, the weight of heat sink 310 may crack, damage or cause heat sink 310 to separate from baseplate 140. Thus, it may be advantageous to optimize heat dissipation, weight, cost, machinability and other features of when selecting a heat sink. Accordingly, the heat sink 310 may be specific to the application of device 300.

With some examples, measures may be taken in order to protect against shock and vibration and to protect electronic components against moisture and corrosive agents. In particular, the assembly may be potted with encapsulant 320. Encapsulant 320 may be a solid or gelatinous compound that provides resistance to shock and vibration, and assists with exclusion of moisture and corrosive agents. Encapsulant 320 may comprise a compound such as polyurethane or silicone.

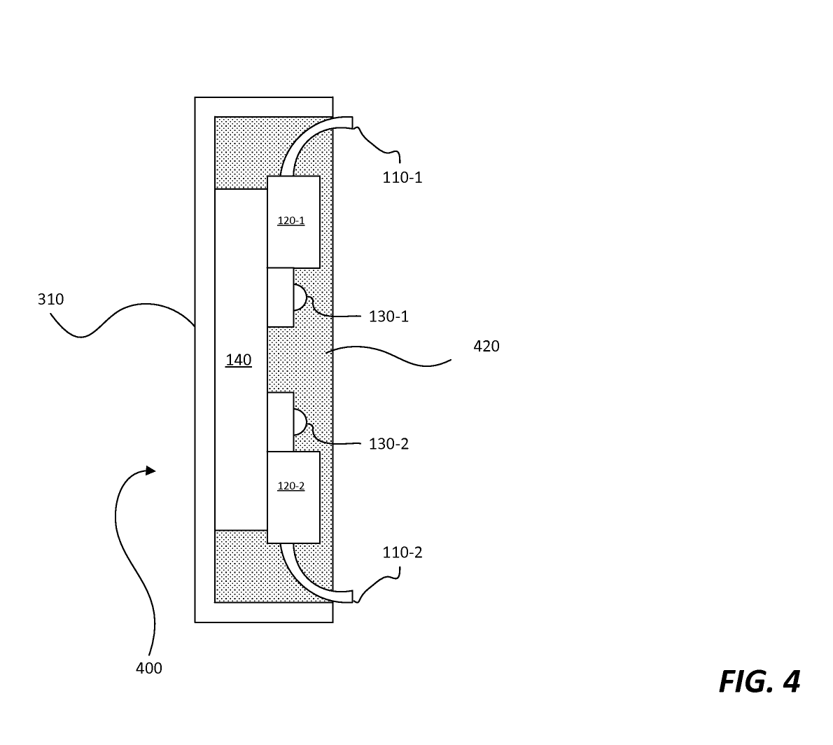

FIG. 4 illustrates device 400 from a side view. Discrete electronic devices 120-1 and 120-2 are shown affixed to baseplate 140 by screws 130-1 and 130-2 respectively. Examples, however are not to be limited in this context. Specifically, the discrete electronic devices 120-a may be affixed to the baseplate 140 by any of a variety of techniques, such as for example, riveting, crimping, welding, soldering, brazing, taping, cementing, or using adhesives (e.g., thermal epoxy, or the like.)

It is to be appreciated, that the discrete electronic devices 120-a may include any number of electrical leads 110-ab, with the number of leads being dependent upon the nature of each individual discrete electronic device 120-a. However, the discrete electronic devices 120-a are shown having electrical leads 110-1 and 110-2 for convenience and clarity. Application specific heat sink 310 has been mounted onto baseplate 140. Measures may be taken in order to protect against shock and vibration and to protect electronic components against moisture and corrosive agents. In this example, the assembly has been overmolded via injection molding. In this procedure, materials have been placed into a heated barrel, mixed, and forced into the cavity formed by heat sink 310 where the material cools and hardens to configuration 420. Example materials include metals, glasses, elastomers, and confections, as well as thermoplastic and thermosetting polymers.

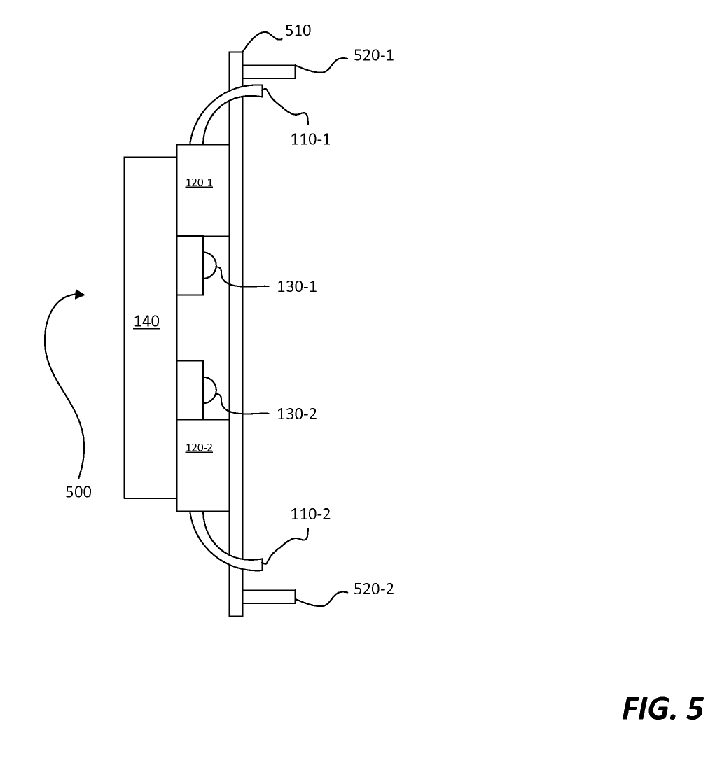

FIG. 5 illustrates device 500 from a side view. Discrete electronic devices 120-1 and 120-2 are shown affixed to baseplate 140 by screws 130-1 and 130-2 respectively. Examples, however are not to be limited in this context. Specifically, the discrete electronic devices 120-a may be affixed to the baseplate 140 by any of a variety of techniques, such as for example, riveting, crimping, welding, soldering, brazing, taping, cementing, or using adhesives (e.g., thermal epoxy, or the like.)

It is to be appreciated, that the discrete electronic devices 120-a may include any number of electrical leads 110-ab, with the number of leads being dependent upon the nature of each individual discrete electronic devices 120-a. However, the discrete electronic devices 120-a are shown having electrical leads 110-1 and 110-2 for convenience and clarity. It may be desirable to mechanically support and electronically connect electronic devices 120-a. In this example, electrical leads 110-a have been soldered onto printed circuit board (PCB) 510 having electrical leads 520-a, such that printed circuit board 510 mechanically supports and electrically connects discrete electronic devices 120-a. PCB 510 may include conductive tracks, pads and other features etched from electrically conductive sheets laminated onto a non-conductive substrate. Using PCB 510 may be less expensive and faster than other methods of electronically connecting discrete electronic device 120 because the procedure for assembly may be automated. There may be additional benefits to using PCB 510, for example wiring errors may be reduced. Alternative ways of electronically connecting discrete electronic devices 120 are possible, including manual wire wrapping and point-to-point construction using terminal strips.

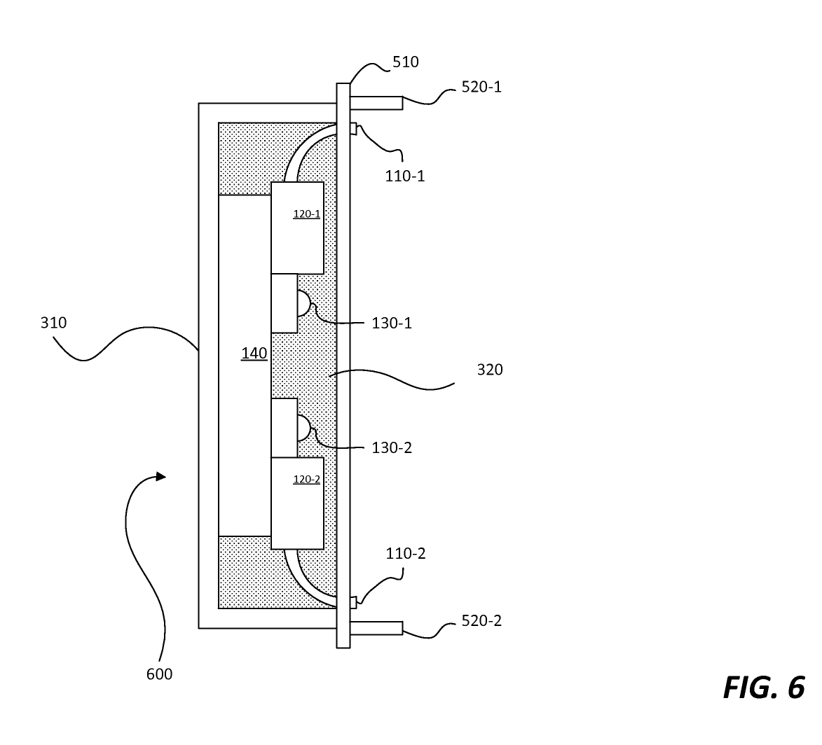

FIG. 6 illustrates device 600 from a side view. Discrete electronic devices 120-1 and 120-2 are shown affixed to baseplate 140 by screws 130-1 and 130-2 respectively. Examples, however are not to be limited in this context. Specifically, the discrete electronic devices 120-a may be affixed to the baseplate 140 by any of a variety of techniques, such as for example, riveting, crimping, welding, soldering, brazing, taping, cementing, or using adhesives (e.g., thermal epoxy, or the like.)

It is to be appreciated, that the discrete electronic devices 120-a may include any number of electrical leads 110-ab, with the number of leads being dependent upon the nature of each individual discrete electronic device 120-a. However, the discrete electronic devices 120-a are shown having electrical leads 110-1 and 110-2 for convenience and clarity. Electrical leads 110-1 and 110-2 have been soldered onto PCB 510 having electrical leads 520-1 and 520-2. Application specific heat sink 310 has been mounted onto baseplate 140. The assembly has then been potted with encapsulant 320.

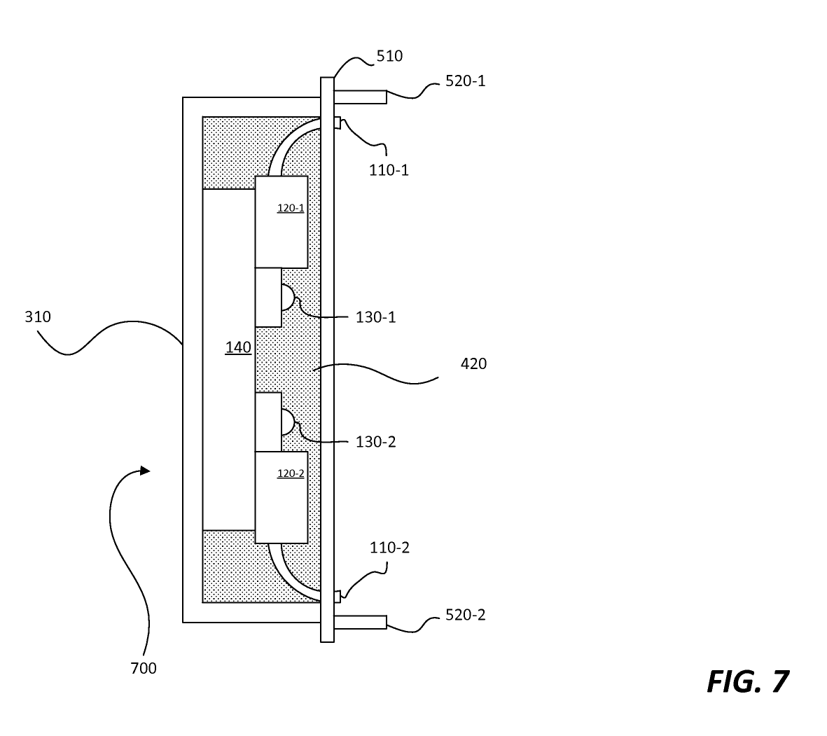

FIG. 7 illustrates device 700 from a side view. FIG. 7 shows discrete electronic devices 120-1 and 120-2 affixed to baseplate 140 by screws 130-1 and 130-2 respectively. Examples, however are not to be limited in this context. Specifically, the discrete electronic devices 120-a may be affixed to the baseplate 140 by any of a variety of techniques, such as for example, riveting, crimping, welding, soldering, brazing, taping, cementing, or using adhesives (e.g., thermal epoxy, or the like.)

It is to be appreciated, that the discrete electronic devices 120-a may include any number of electrical leads 110-ab, with the number of leads being dependent upon the nature of each individual discrete electronic device 120-a. However, the discrete electronic devices 120-a are shown having electrical leads 110-1 and 110-2 for convenience and clarity. In this example, electrical leads 110-1 and 110-2 are oriented away from baseplate 140. Electrical leads 110-1 and 110-2 have been soldered onto PCB 510 having electrical leads 520-1 and 520-2. Application specific heat sink 310 has been mounted onto baseplate 140. The assembly has been overmolded via injection molding. In this procedure, materials have been placed into a heated barrel, mixed, and forced into the cavity formed by heat sink 310 where the material cools and hardens to configuration 420. Example materials include metals, glasses, elastomers, and confections, as well as thermoplastic and thermosetting polymers.

It should be understood that various changes and modifications to the presently preferred embodiments described herein will be apparent to those skilled in the art. Such changes and modifications can be made without departing from the spirit and scope of the present invention and without diminishing its attendant advantages. It is therefore intended that such changes and modifications be covered by the appended claims.

What is claimed is:

1. An electronic power module comprising:
a baseplate; and
a plurality of internally isolated discrete electronic devices mounted to the baseplate;
wherein each of the plurality of internally isolated discrete electronic devices includes electrical leads oriented away from the baseplate.

2. The electronic power module of claim 1 further comprising:
a thermal interface material disposed between the plurality of internally isolated discrete electronic devices and the baseplate.

3. The electronic power module of claim 2 wherein:
the thermal interface material comprises beryllium oxide, aluminum nitride, zinc oxide, or silicon dioxide.

4. The electronic power module of claim 1 wherein:
the baseplate comprises copper.

5. The electronic power module of claim 1 wherein:
the electrical leads are coupled to a printed circuit board (PCB).

6. The electronic power module of claim 5 wherein:
the electrical leads are coupled to the PCB by soldering.

7. The electronic power module of claim 1 wherein:
the baseplate is coupled to at least one heat sink.

8. The electronic power module of claim 1 wherein:
the plurality of internally isolated discrete electronic devices and the baseplate are overmolded via injection molding.

9. The electronic power module of claim 1 wherein:
the plurality of internally isolated discrete electronic devices and the baseplate are potted using an encapsulant.

10. The electronic power module of claim 1 wherein:
each discrete electronic device is either a thyristor, a diode, or a transistor.

11. A method for making an electronic power module comprising:
mounting a plurality of internally isolated discrete electronic devices to a baseplate, wherein each of the plurality of internally isolated discrete electronic devices includes electrical leads, such that the leads are oriented away from the baseplate.

12. The method of claim 11 further comprising:
disposing a thermal interface material between the plurality of internally isolated discrete electronic devices and the baseplate.

13. The method of claim 12 wherein:
the thermal interface material comprises beryllium oxide, aluminum nitride, zinc oxide, or silicon dioxide.

14. The method of claim 11 wherein:
the baseplate comprises copper.

15. The method of claim 11 further comprising:
coupling the electrical leads to a printed circuit board (PCB).

16. The method of claim 11 further comprising:
soldering the electrical leads to a printed circuit board (PCB).

17. The method of claim 11 further comprising:
coupling the baseplate to at least one heat sink.

18. The method of claim 11 further comprising:
overmolding the plurality of internally isolated discrete electronic devices and the baseplate via injection molding.

19. The method of claim 11 further comprising:
potting the plurality of internally isolated discrete electronic devices and the baseplate using an encapsulant.

20. The method of claim 11 wherein:
each discrete electronic device is either a thyristor, a diode, or a transistor.
